(19) United States
(12) Patent Application Publication
(10) Pub. No.: US 2020/0250845 A1
(43) Pub. Date: Aug. 6, 2020

(54) EVALUATION METHOD AND INFORMATION PROCESSING APPARATUS

(71) Applicant: FUJITSU LIMITED, Kawasaki-shi (JP)

(72) Inventors: Kosuke Fukano, Ota (JP); Fumiyuki Takahashi, Atsugi (JP); Takuya Kozaki, Yokohama (JP)

(73) Assignee: FUJITSU LIMITED, Kawasaki-shi (JP)

(21) Appl. No.: 16/741,933

(22) Filed: Jan. 14, 2020

(30) Foreign Application Priority Data
Jan. 31, 2019 (JP) 2019-016350

(51) Int. Cl. G06T 7/564; G06T 7/60; G06F 30/23; G06T 7/73

(52) U.S. Cl. CPC G06T 7/564; G06T 7/73; G06F 30/23; G06T 7/60

(57) ABSTRACT

An evaluation method includes: identifying by a computer, when detecting that a hole formed in a structure is included in a target image that includes a captured image of the structure, a shape of a contour of the hole on the target image; identifying a part of the three-dimensional model such that, when a three-dimensional model according to three-dimensional design data of the structure is projected onto the target image such that a projected image of the three-dimensional model onto the target image corresponds to the captured image of the structure included in the target image, the part on the projected image corresponds to the shape; and outputting evaluation information related to a position at which the hole is formed in the structure, based on a result of comparison between the identified part and a part of the three-dimensional model corresponding to the three-dimensional design data of the hole.

### CROSS-REFERENCE TO RELATED APPLICATION

This application is based upon and claims the benefit of the prior Japanese Patent Application No. 2019-016350, filed on Jan. 31, 2019, the entire contents of which are incorporated herein by reference.

### FIELD

The embodiments discussed herein are related to an evaluation method and an information processing apparatus.

### BACKGROUND

In the related art, there is known a technique for displaying a projected image of a three-dimensional model of a structure to be superimposed on a captured image of the structure. For example, in the related art, a process for identifying the display posture of the three-dimensional model is performed based on edge lines extracted from the captured image. In addition, this technique is used, for example, to inspect whether or not a manufactured structure is different from 3D CAD (Computer Aided Design) data created in advance.

Related techniques are disclosed in, for example, Japanese Laid-Open Patent Publication No. 2018-128803.

### SUMMARY

According to an aspect of the embodiments, an evaluation method includes: identifying by a computer, when detecting that a hole formed in a structure is included in a target captured image that includes a captured image of the structure, a shape of a contour of the hole on the target captured image; identifying a part of the three-dimensional model such that, when a three-dimensional model according to three-dimensional design data of the structure is projected onto the target captured image such that a projected image of the three-dimensional model onto the target captured image corresponds to the captured image of the structure that is included in the target captured image, the part on the projected image corresponds to the shape; and outputting evaluation information related to a position at which the hole is formed in the structure, based on a result of comparison between the identified part and a part of the three-dimensional model corresponding to the three-dimensional design data of the hole.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a view illustrating an example of a functional configuration of an information processing apparatus according to an embodiment;

FIG. 2 is a view illustrating an example of a hole in a 3D model;

FIG. 3 is a view for explaining a deviation of the center of an ellipse;

FIG. 4 is a view for explaining a detection range;

FIG. 5 is a view for explaining a detection of a hole on a captured image;

FIG. 6 is a view for explaining a process of identifying a shape;

FIG. 7 is a view for explaining binarization;

FIG. 8 is a view for explaining a detection of a perfect circle;

FIG. 9 is a view for explaining a back projection;

FIG. 10 is a view illustrating an example of an area difference;

FIG. 11 is a view illustrating an example of a center-to-center distance;

FIG. 12 is a view illustrating an example of a difference between a major axis and a minor axis;

FIG. 13 is a view illustrating an example of a formed angle;

FIG. 14 is a view for explaining a correction of the center of a hole;

FIG. 15 is a view for explaining a calculation of an error;

FIG. 16 is a view for explaining a detection of a hole in a 3D model;

FIG. 17 is a view for explaining a detection of a hole in a 3D model;

FIG. 18 is a view for explaining the center and radius of a hole in a 3D model;

FIG. 19 is a view illustrating an example of evaluation information;

FIG. 20 is a flowchart illustrating the flow of an evaluation process;

FIG. 21 is a flowchart illustrating the flow of a identifying process;

FIG. 22 is a flowchart illustrating the flow of a process of detecting a perfect circle; and

FIG. 23 is a view illustrating an example of a hardware configuration.

### DESCRIPTION OF EMBODIMENTS

The technique described above has a problem in that it may be difficult to improve the accuracy of evaluation on a position of a hole formed in the structure.

Here, for example, a structure may have a hole through which a bolt is to pass. At this time, when a deviation between the position of the actual hole and the position of a designed hole exceeds an allowable range, the bolt is unable to pass through the hole, and for example, structures are unable to be assembled with each other.

According to the related art, a hole on the captured image and a designed hole in the three-dimensional model may be displayed simultaneously in the superimposed image obtained by superimposing the projected image of the three-dimensional model on the captured image of the structure. Meanwhile, since noise is generated in the captured image due to the influence of the background, the pattern of the surface of the structure, and the shadow, the position of the hole on the superimposed image may not be accurately identified. In addition, since the hole of the structure may appear as an ellipse in the captured image, the center of the hole or the like is unable to be accurately grasped, and it may be difficult to evaluate an error between the position of the hole on the captured image and the position of the designed hole with a high accuracy.

Hereinafter, embodiments of an evaluation method and an information processing apparatus will be described in detail with reference to the accompanying drawings. In addition, the embodiments do not limit the present disclosure and may be appropriately combined with each other within the scope that does not cause any inconsistency.

As an example, an evaluation method, an evaluation program, and an information processing apparatus of an embodiment are used to check whether or not a manufactured structure is different from a three-dimensional model of the structure. For example, the information processing apparatus may generate a projected image after matching the posture of a structure of which image is captured with the posture of a three-dimensional model and display the projected image to be superimposed on the captured image.

A user may determine whether or not the structure is being manufactured as designed, by looking at the superimposed image obtained by superimposing the projected image on the captured image. Here, when a hole through which a bolt is to pass is excessively deviated from the designed position of the structure, structures are unable to be assembled with each other by causing the bolt to pass through the hole. Therefore, the user checks whether or not the position of the hole is excessively deviated by looking at the superimposed image, but it is difficult to quantitatively evaluate the size of the deviation only from the appearance. For example, the evaluation method, the evaluation program, and the information processing apparatus according to the embodiment may provide the user with information for evaluating the deviation of a hole.

In the following description, the term “three-dimensional” may be abbreviated as “3D.” For example, three-dimensional design data may be abbreviated as 3D design data, and a three-dimensional model may be described as a 3D model.

(Functional Configuration)

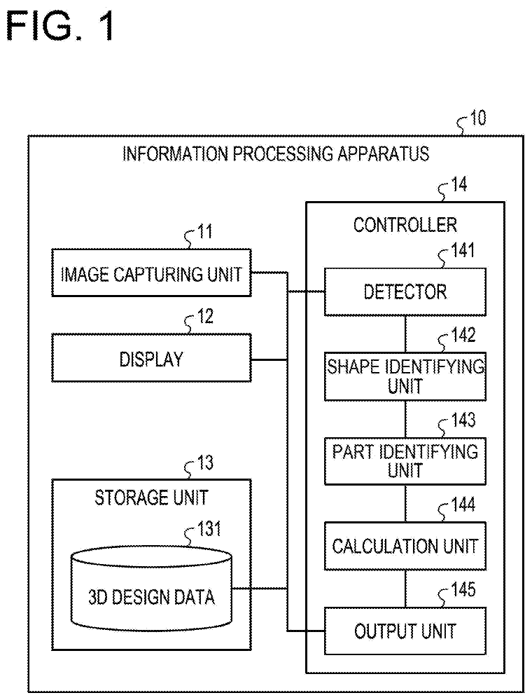

The functional configuration of the information processing apparatus according to the embodiment will be described with reference to FIG. 1. FIG. 1 is a view illustrating an example of the functional configuration of the information processing apparatus according to the embodiment. For example, an information processing apparatus 10 is a smartphone, a tablet terminal, a personal computer or the like. As illustrated in FIG. 1, the information processing apparatus 10 includes an image capturing unit 11, a display 12, a storage unit 13 and a controller 14.

The image capturing unit 11 captures an image. For example, the image capturing unit 11 is a camera. In addition, the display 12 displays an image under a control by the controller 14. For example, the display 12 is a touch panel display or the like.

The storage unit 13 is an example of a storage device that stores data, a program executed by the controller 14, and so on, such as a hard disk, a memory or the like. The storage unit 13 stores 3D design data 131.

The 3D design data 131 is data created by a 3D CAD or the like for constructing a three-dimensional model of a structure. According to the 3D design data 131, a projected image of a 3D model of a designated structure may be generated. The controller 14 performs a process related to the 3D model by appropriately referring to the 3D design data 131.

The controller 14 is implemented by, for example, a CPU (Central Processing Unit), an MPU (Micro Processing Unit), a GPU (Graphics Processing Unit) or the like that executes a program stored in an internal storage device using a RAM as a work area. In addition, the controller 14 may be implemented by an integrated circuit such as an ASIC (Application Specific Integrated Circuit), a FPGA (Field Programmable Gate Array) or the like. The controller 14 includes a detector 141, a shape identifying unit 142, a part identifying unit 143, a calculation unit 144, and an output unit 145.

The detector 141 detects that a hole formed in a structure is included in a target captured image that includes a captured image of the structure. It is assumed that, at the time point when the detection process by the detector 141 is performed, a superimposed image has been obtained in which the captured image of the structure, which is included in the target captured image obtained by the image capturing unit 11, and the projected image of the 3D model are displayed to be superimposed on each other.

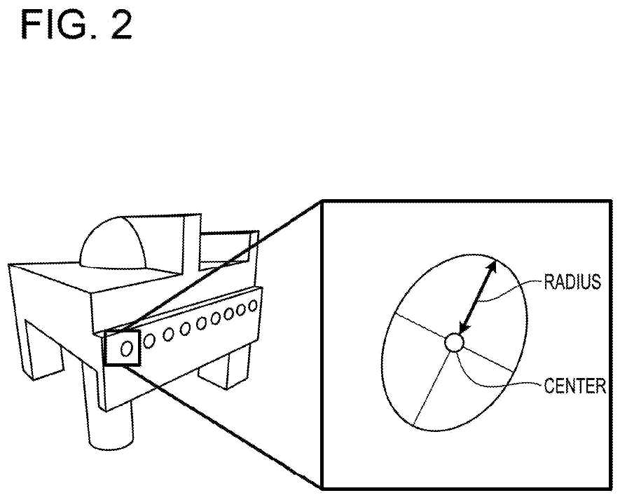

Here, a hole designed as a perfect circle may be displayed as an ellipse in the projected image of the 3D model based on the design, as illustrated in FIG. 2. FIG. 2 is a view illustrating an example of a hole in the 3D model. When the designed hole is a perfect circle, the radius of the hole is equal in any direction. Meanwhile, as illustrated in FIG. 2, since the hole is displayed as an ellipse in the projected image, for example, the radius is extended in the long axis direction and reduced in the short axis direction.

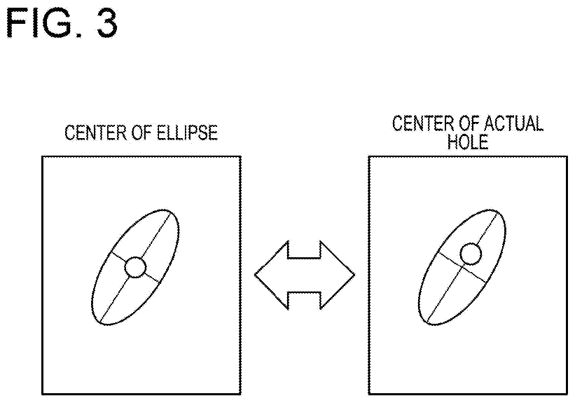

Further, as illustrated in FIG. 3, depending on the inclination of the 3D model when the projected image is generated, for example, a point corresponding to the center of the actual hole may not coincide with the center of the ellipse. FIG. 3 is a view for explaining the deviation of the center of the ellipse.

The detector 141 detects a range around the hole in the 3D model on the projected image. In other words, in a case where the structure is manufactured according to the design, the detector 141 detects a region where the hole is estimated to appear in the target captured image.

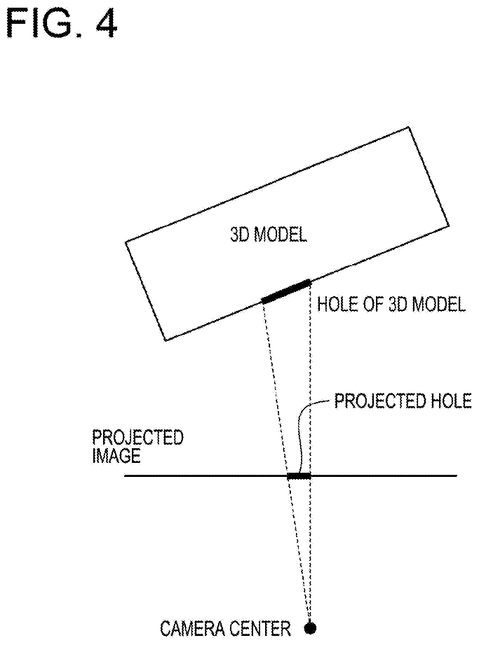

As illustrated in FIG. 4, the detector 141 obtains intersection points where straight lines that connect the point indicating the center of a camera and the multiple edge points of the hole in the 3D model to each other intersect with the plane indicating the target captured image. FIG. 4 is a view for explaining a detection range.

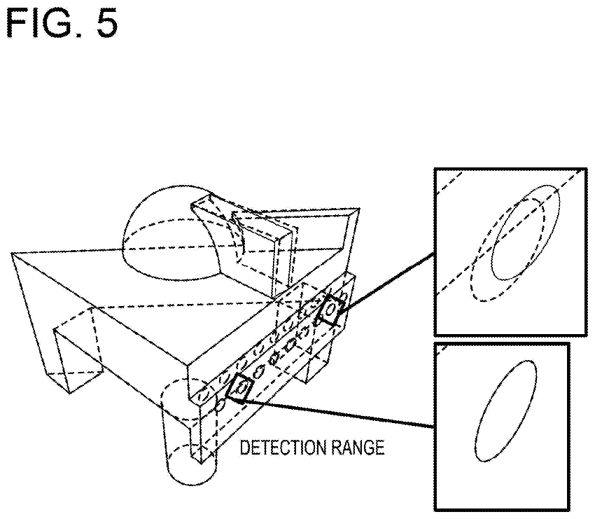

Then, the detector 141 detects a range including the region surrounded by the obtained intersection points. As illustrated in FIG. 5, the detector 141 may make the detection range rectangular. FIG. 5 is a view for explaining the detection of the hole on the target captured image. In addition, the detector 141 may determine the length of each side of the rectangle to be detected, based on the radius of the designed hole, the major axis and minor axis of the hole in the 3D model, and the like.

Here, while it is an ideal state that the position of the hole in the structure and the position of the hole on the projected image coincide with each other, the positions of the holes may actually deviate from each other. Further, as illustrated in FIG. 5, the size of the deviation may be different for each hole. In addition, in FIG. 5 and the subsequent figures, a broken line in the target captured image indicates the projected image.

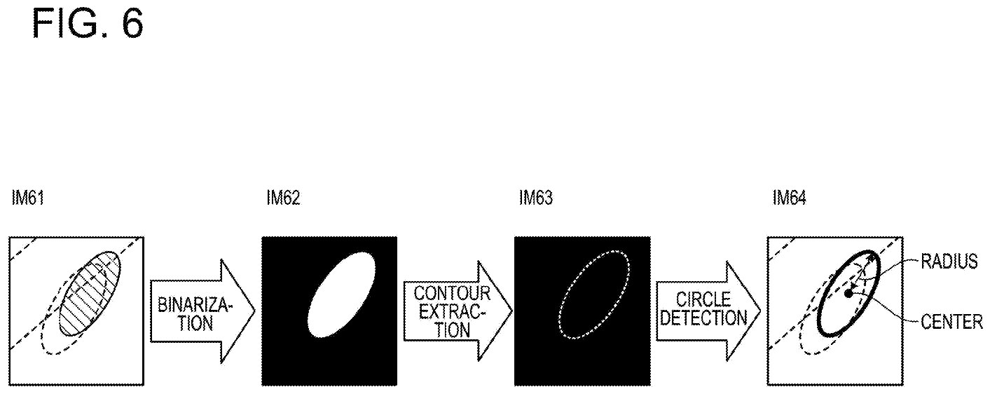

When it is detected that a hole formed in the structure is included in the target captured image that includes the captured image of the structure, the shape identifying unit 142 identifies the shape of the contour of the hole on the target captured image. The procedure of the process of identifying the shape by the shape identifying unit 142 will be described with reference to FIG. 6. FIG. 6 is a view for explaining the process of identifying the shape.

In FIG. 6, IM61 is an image within the detection range detected by the detector 141. In the image of the IM61, there exists a figure that looks like an ellipse indicated by a solid line and a pattern. However, even when the figure corresponds to a hole intended to be formed as a perfect circle, this figure may not be an exact ellipse due to the noise occurring on an image from the influence of manufacturing accuracy, background, structure surface pattern, and shadow.

Therefore, within a range determined based on, a size of a first designed hole included in the three-dimensional model on the projected image, the shape identifying unit 142 identifies a shape of the contour of a second hole formed in the structure on the target captured image. Here, the shape identifying unit 142 identifies the shape assuming that the shape of the contour of the second hole on the target captured image is an ellipse. In addition, the detection range is an example of a range determined based on the size of the first hole on the projected image.

First, the shape identifying unit 142 performs binarization of the image represented in IM61 of FIG. 6. Here, the shape identifying unit 142 converts an ellipse candidate region into a value corresponding to true, and converts the other regions into a value corresponding to false. The value corresponding to true and the value corresponding to false may be a value indicating a first color and a value indicating a second color different from the first color, respectively, and may be any values as long as the values are unified throughout the process of the shape identifying unit 142. For example, the value corresponding to true and the value corresponding to false may be 1 and 0, respectively, or may be 255 and 0, respectively.

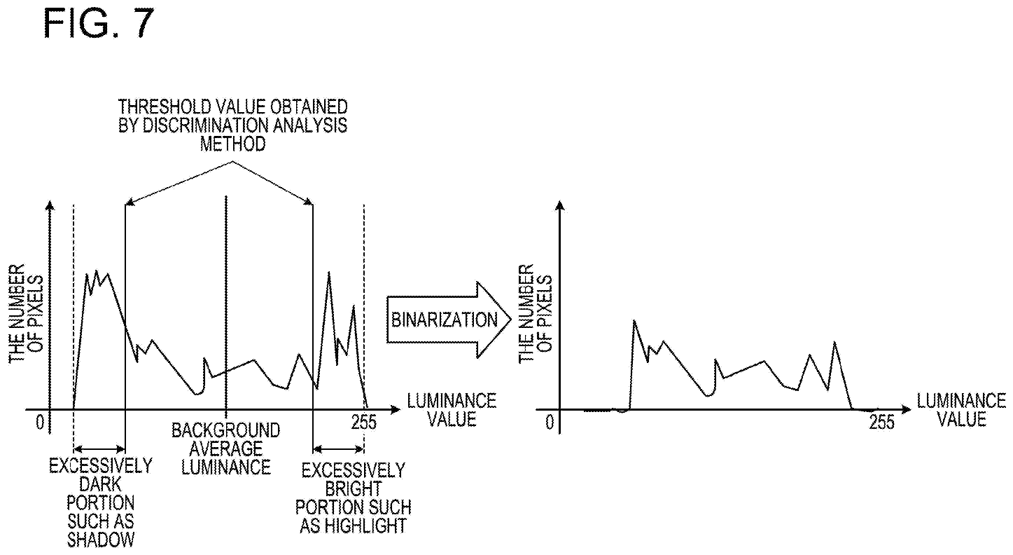

The shape identifying unit 142 may perform the binarization using a superposition result to be described in FIG. 7. FIG. 7 is a view for explaining the binarization. In addition, the shape identifying unit 142 may perform the binarization according to known methods such as Otsu binarization, Grabcut, morphology and the like.

Here, it is assumed that the range of luminance value of an image is, for example, 0 to 255. As illustrated in FIG. 7, first, the shape identifying unit 142 calculates a background average value that is an average value of luminance of pixels of the image of IM61 in FIG. 6. Next, the shape identifying unit 142 uses a discrimination analysis method to calculate a luminance threshold value for dividing pixels whose luminance value is equal to or smaller than the background average value into two groups, as a first threshold value. In addition, the shape identifying unit 142 uses the discrimination analysis method to calculate a luminance threshold value for dividing pixels whose luminance value is equal to or larger than the background average value into two groups, as a second threshold value.

Then, the shape identifying unit 142 determines that among pixels of the image in the detection range, a pixel whose luminance value is included in the range from the first threshold value to the second threshold value greater than the first threshold value is true. In addition, the shape identifying unit 142 determines that a pixel whose luminance value is not included in the range is false. The shape identifying unit 142 identifies the shape of the contour of the hole on the target captured image based on the image binarized into true and false. In addition, a pixel whose luminance value is equal to or smaller than the first threshold corresponds to an excessively dark portion such as a shadow. Further, a pixel whose luminance value is equal to or larger than the second threshold corresponds to an excessively bright portion such as a highlight.

For example, as represented in IM62 of FIG. 6, the shape identifying unit 142 converts the pixel whose luminance value is within the range from the first threshold value to the second threshold value, into white, and converts the pixel whose luminance value is not within the range from the first threshold value to the second threshold value, into black. As a result, the region where an ellipse is likely to exist becomes clearer.

Here, the shape identifying unit 142 performs the contour extraction from the binarized image as represented in IM62 of FIG. 6. The shape identifying unit 142 may extract the contour of the ellipse by a known method such as a Suzuki85 algorithm. IM63 of FIG. 6 is an image in which the contour of the ellipse extracted by the shape identifying unit 142 is indicated by a dotted line.

Then, the shape identifying unit 142 detects the ellipse based on the image of IM63 in FIG. 6, and identifies the major axis, the minor axis, and the center of the ellipse as represented in IM64 of FIG. 6. Specifically, the shape identifying unit 142 identifies information that enables the ellipse represented by the identified contour to be projected as a perfect circle in the same space (CAD coordinate space) as that of the 3D model. In the following description, projecting a figure identified from a captured image onto the CAD coordinate space will be referred to as a back projection.

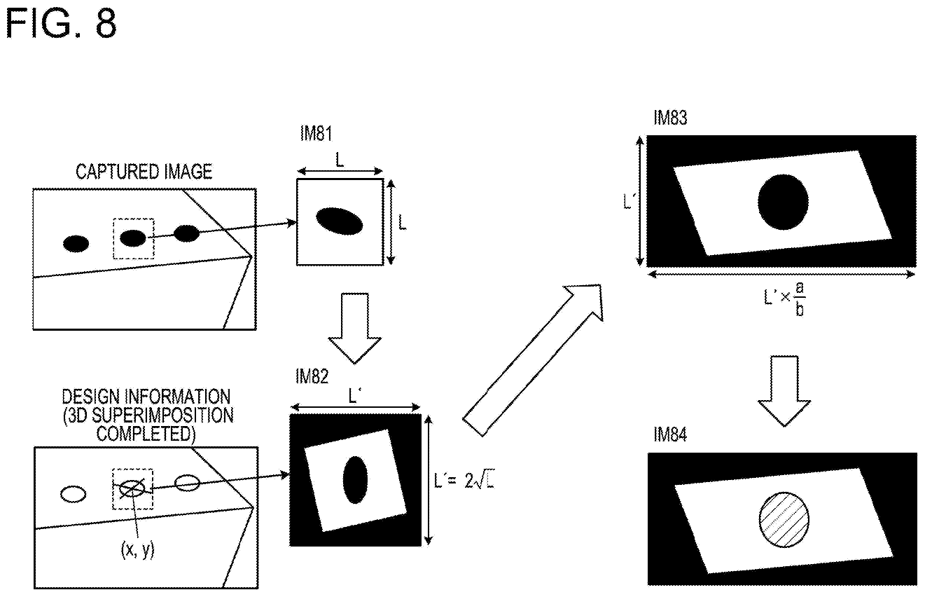

The shape identifying unit 142 may detect a perfect circle using a superposition result to be described in FIG. 8. FIG. 8 is a view for explaining the detection of a perfect circle. In addition, the shape identifying unit 142 may detect a perfect circle by a known method such as Hough transformation.

The detection of a perfect circle by the shape identifying unit 142 will be described with reference to FIG. 8. As illustrated in FIG. 8, first, based on the identified contour of the ellipse, the shape identifying unit 142 cuts out a rectangular region around the ellipse from the target captured image as represented in IM81 of FIG. 8. Here, it is assumed that the shape identifying unit 142 cuts out a square region including the entire ellipse and having the length L of one side.

Next, the shape identifying unit 142 refers to the design information acquired from the 3D design data 131 to acquire the angle of the major axis of the ellipse on the projected image of the hole in the 3D model. Based on the acquired angle, the shape identifying unit 142 performs affine transformation of the cut-out rectangular region to adjust the position and angle of the ellipse. For example, the shape identifying unit 142 performs the transformation such that the major axis direction of the ellipse is parallel to the vertical direction of the transformed image.

Further, as represented in IM82 of FIG. 8, the shape identifying unit 142 cuts out a square image including the entire transformed image and having the length L′ of one side. The L′ is, for example, a value obtained by multiplying L by route 2. Then, as represented in IM83 of FIG. 8, the shape identifying unit 142 corrects the aspect ratio of the square image based on the ellipticity of the ellipse on the projected image of the hole in the 3D model. Here, assuming that the major axis of the ellipse is “a” and the minor axis is “b,” the ellipticity is a/b. For example, when the major axis direction of the ellipse is parallel to the vertical direction of the image, the shape identifying unit 142 corrects the aspect ratio by multiplying the horizontal length L′ of the image by the ellipticity a/b.

As represented in IM84 of FIG. 8, the shape identifying unit 142 calculates the center and radius of a circle by Hough transformation or the like from the image of which aspect ratio has been corrected, to detect a perfect circle. In addition, in IM84 of FIG. 8, the detected perfect circle is displayed in an oblique line pattern for the purpose of description.

The part identifying unit 143 identifies a part of the 3D model such that, when the 3D model according to the 3D design data of the structure is projected onto the target captured image such that the projected image of the 3D model onto the target captured image corresponds to the captured image of the structure that is included in the target captured image, the part on the projected image corresponds to the shape. That is, the part identifying unit 143 identifies a corresponding part of the 3D model when the ellipse of which contour has been identified by the shape identifying unit 142 is backwardly projected, based on the perfect circle detected by the shape identifying unit 142. As described above, the back projection refers to projecting a figure identified from a captured image onto the CAD coordinate space.

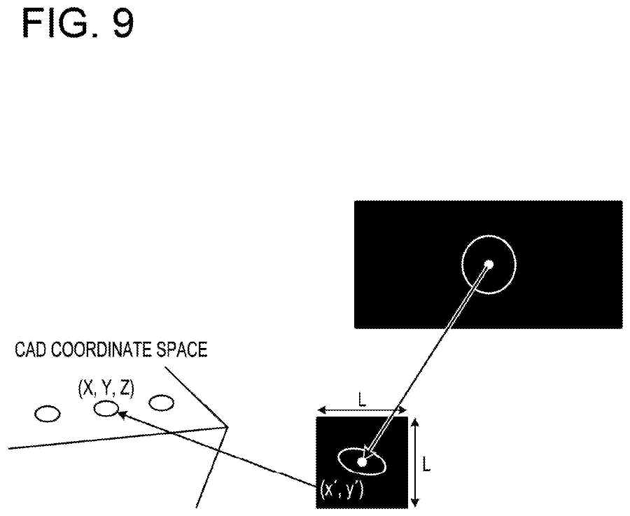

First, as illustrated in FIG. 9, the part identifying unit 143 identifies the coordinate (x′, y′) of the center of the ellipse of which contour has been identified, in the target captured image, by executing the procedure of the shape identifying unit 142 in reverse. FIG. 9 is a view for explaining the back projection. Further, the part identifying unit 143 transforms the coordinate (x′, y′) into a CAD space coordinate (X, Y, Z). For example, the part identifying unit 143 may perform the transformation into the CAD space coordinate using information such as the inclination of the 3D model when the projected image is generated.

Here, the shape identifying unit 142 may identify the shape by combining a plurality of methods set in advance for each procedure for identifying the shape. For example, it is assumed that the shape identifying unit 142 is set in advance to select either binarization using a superimposition result or Otsu's binarization as a binarization method. Further, it is assumed that the shape identifying unit 142 is set in advance to select either detection of a perfect circle using a superimposition result or Hough transformation as a method of detecting a perfect circle. At this time, the shape identifying unit 142 may finally obtain, for example, four types of detection results.

The calculation unit 144 calculates a cost function for each of, for example, four detection results obtained by the shape identifying unit 142. Then, the output unit 145 outputs evaluation information based on a result of comparison between a part identified based on a shape identified by using a combination having the smallest predetermined cost function, and a part of the 3D model corresponding to the 3D design data of the hole. Here, the calculation unit 144 calculates an error between the ellipse of the structure on the target captured image and the ellipse on the projected image of the 3D model. The error is, for example, a distance between the centers of the ellipses.

The calculation unit 144 calculates a cost function E(C, C*) as expressed by the following equation (1). The “C” represents an ellipse of which shape is identified by the shape identifying unit 142. The “C*” represents an ellipse of the projected image of the 3D model.

E(C,C*)=Eₐᵣₑₐ(C,C*)+Eₚₒₛ(C,C*)+Eₛₕₐₚₑ(C,C*)+E_{angle}(C,C*) (1)

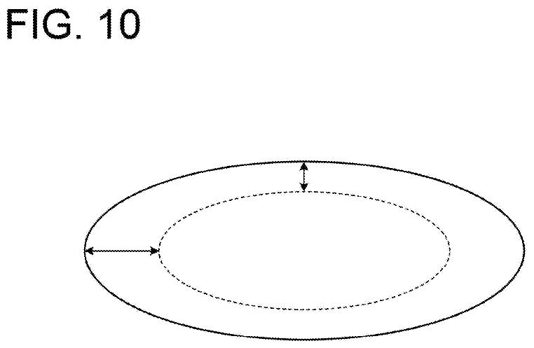

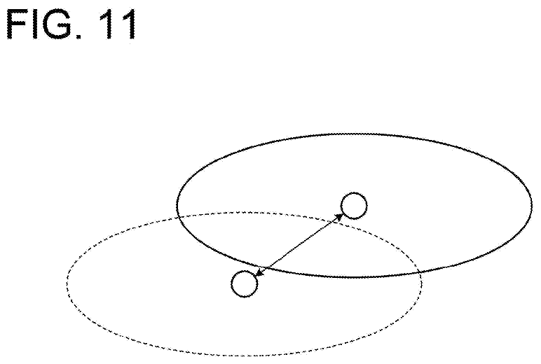

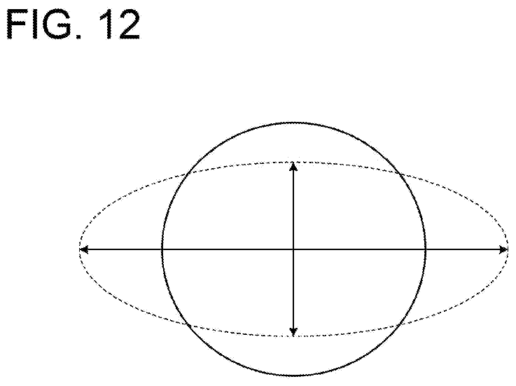

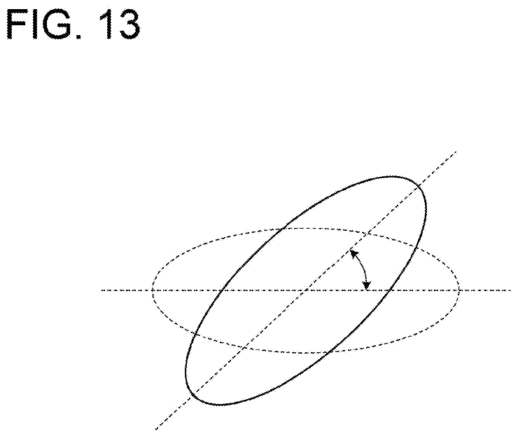

Eₐᵣₑₐ(C,C*) represents a difference in area between ellipses. FIG. 10 is a view for explaining the area difference. Eₚₒₛ(C, C*) is a distance between the centers of the ellipses. FIG. 11 is a view for explaining the center-to-center distance. Eₛₕₐₚₑ(C, C*) represents a difference between the major axis and the minor axis of an ellipse. FIG. 12 is a view for explaining the difference between the major axis and the minor axis. Eₛₕₐₚₑ(C, C*) represents an angle formed between the major axis of the ellipse and a horizontal straight line. FIG. 13 is a view for explaining the formed angle.

In this way, the cost function increases with the increase in an area difference, a center-to-center distance, and a formed angle between a first ellipse corresponding to the identified part and a second ellipse corresponding to a part of the 3D model corresponding to the 3D design data of the hole, and a distance between the major axis and the minor axis of the second ellipse.

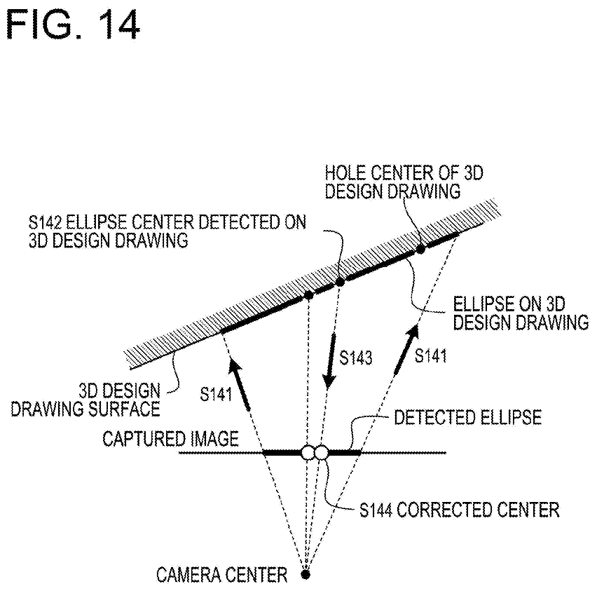

The calculation unit 144 calculates an error for the combination having the smallest cost function. The error is an example of evaluation information. First, the calculation unit 144 performs a correction of the center of the hole in order to calculate the error. FIG. 14 is a view for explaining the correction of the center of the hole.

First, as illustrated in S141 of FIG. 14, the calculation unit 144 projects the first ellipse onto the plane where the hole in the 3D model exists, that is, the same plane as that of the second ellipse. Next, as illustrated in S142 of FIG. 14, the calculation unit 144 detects the projected first ellipse and calculates the center thereof. Furthermore, as illustrated in S143 of FIG. 14, the calculation unit 144 projects the detected ellipse onto the target captured image. Then, as illustrated in S144 of FIG. 14, the calculation unit 144 sets the center projected onto the target captured image as a corrected center.

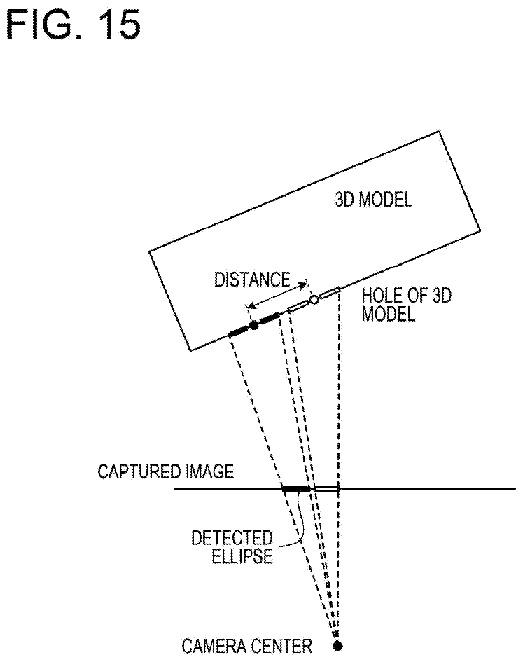

The error calculation will be described with reference to FIG. 15. FIG. 15 is a view for explaining the error calculation. As illustrated in FIG. 15, the calculation unit 144 projects the corrected center of the first ellipse onto the 3D model, and calculates a distance between the projected center and the center of the second ellipse, as an error. The calculation unit 144 calculates the error after regarding the first ellipse and the second ellipse as perfect circles in the 3D model.

Here, a process of detecting a hole in the 3D model will be described. The detector 141 first detects a hole from the 3D model. Then, the detector 141 detects a range in the target captured image based on the detected hole in the 3D model. In addition, the hole in the 3D model may be set in advance in the 3D design data 131, and in this case, the detection of the hole in the 3D model by the detector 141 is unnecessary.

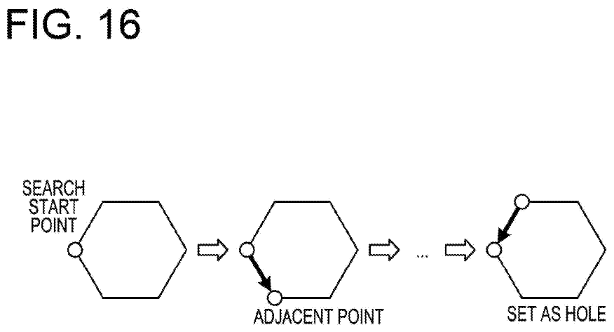

FIG. 16 is a view for explaining the detection of the hole in the 3D model. Here, in the 3D model, the hole is represented by a regular N-polygon. At this time, it may be said that the hole in the 3D model is a set of line segments corresponding to the respect sides of the regular N-polygon. Furthermore, the line segments forming the hole contact only two line segments corresponding to an adjacent side on the regular N-polygon. The detector 141 detects the hole using this property.

FIG. 16 is a view for explaining the detection of the hole in the 3D model. The detector 141 determines whether or not a point adjacent to a search start point that is in contact with only two line segments is in contact with only two line segments. The detector 141 follows a point in contact with only two line segments, and when returning to the search rotation, detects a set of followed line segments, as a hole.

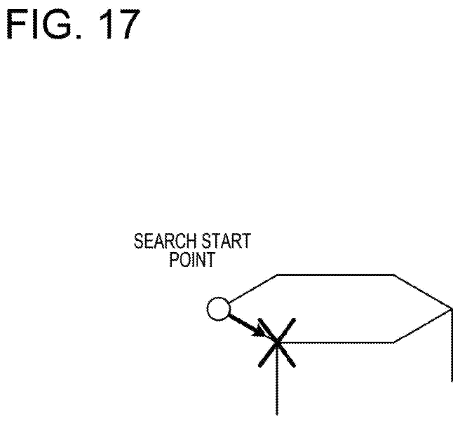

Further, when a point in contact with three or more line segments appears as illustrated in FIG. 17, the detector 141 starts a search from another search start point. FIG. 17 is a view for explaining the detection of the hole in the 3D model.

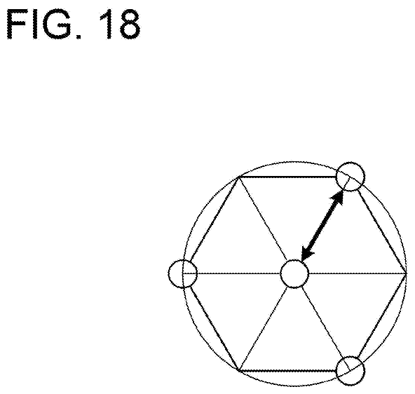

In addition, as illustrated in FIG. 18, the detector 141 extracts, for example, three vertices from a figure formed by a set of line segments detected as the hole, and sets the position of the center of the three vertices as the center of the hole. Further, the distance from the center of the hole to any one of the vertices is set as the radius of the hole. FIG. 18 is a view for explaining the center and radius of the hole in the 3D model. In this way, although the hole in the 3D model is a polygon, since the center and radius thereof can be defined, the hole is treated as a perfect circle in the evaluation process of the embodiment.

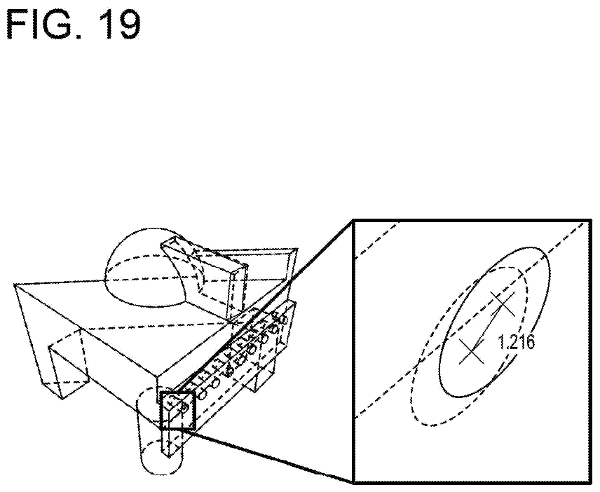

As illustrated in FIG. 19, the output unit 145 displays the center and error of each ellipse on the superimposed image. FIG. 19 is a view illustrating an example of evaluation information. In the example of FIG. 19, the output unit 145 displays, for example, 1.216 as an error.

(Process Flow)

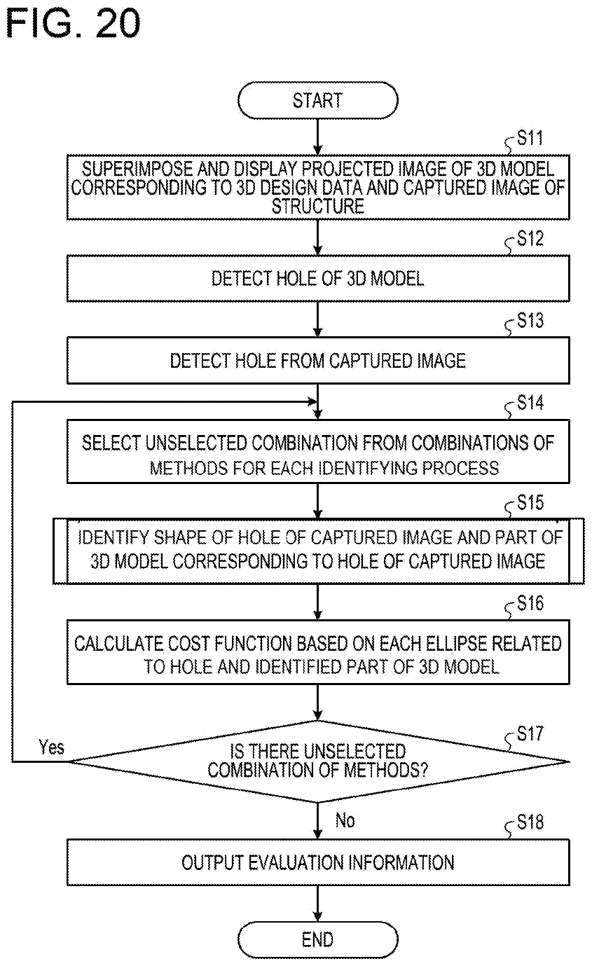

The flow of the process performed by the information processing apparatus 10 will be described with reference to FIGS. 20, 21, and 22. FIG. 20 is a flowchart illustrating the flow of the evaluation process. As illustrated in FIG. 20, first, the information processing apparatus 10 superimposes and displays a projected image of a 3D model corresponding to 3D design data and a captured image of a structure (step S11). Next, the information processing apparatus 10 detects a hole in the 3D model (step S12). Then, the information processing apparatus 10 detects a hole from the captured image (step S13).

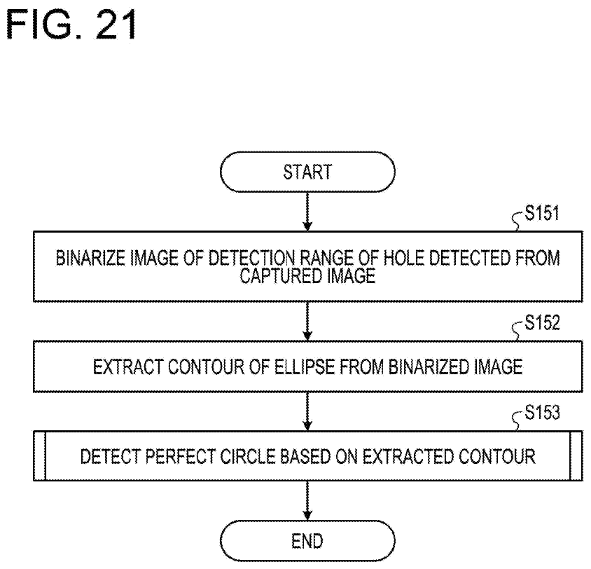

Here, the information processing apparatus 10 selects an unselected combination among the combinations of the methods for each identifying process (step S14). Then, the information processing apparatus 10 identifies a shape of the hole on the captured image and a part of the 3D model corresponding to the hole on the captured image (step S15). Details of the process of step S15 will be described later with reference to FIG. 21.

The information processing apparatus 10 calculates a cost function based on each ellipse related to the hole and the identified part of the 3D model (step S16). Here, the information processing apparatus 10 determines whether or not there is an unselected combination of methods (step S17). When it is determined that there is an unselected combination of methods (Yes in step S17), the information processing apparatus 10 returns to step S14 and repeats the process. Meanwhile, when it is determined that there is no unselected combination of methods (No in step S17), the information processing apparatus 10 outputs evaluation information (Step S18).

Details of step S15 will be described with reference to FIG. 21. FIG. 21 is a flowchart illustrating the flow of the identifying process. As illustrated in FIG. 21, first, the information processing apparatus 10 binarizes an image of a detection range of the hole detected from the captured image (step S151). Next, the information processing apparatus 10 extracts a contour of an ellipse from the binarized image (step S152). Then, the information processing apparatus 10 detects a perfect circle based on the extracted contour (step S153).

In addition, as a method for performing steps S151 and S153, a plurality of methods may be considered. As described with reference to FIG. 20, the information processing apparatus 10 may perform a process on combinations of the plurality of methods and search for an optimal combination.

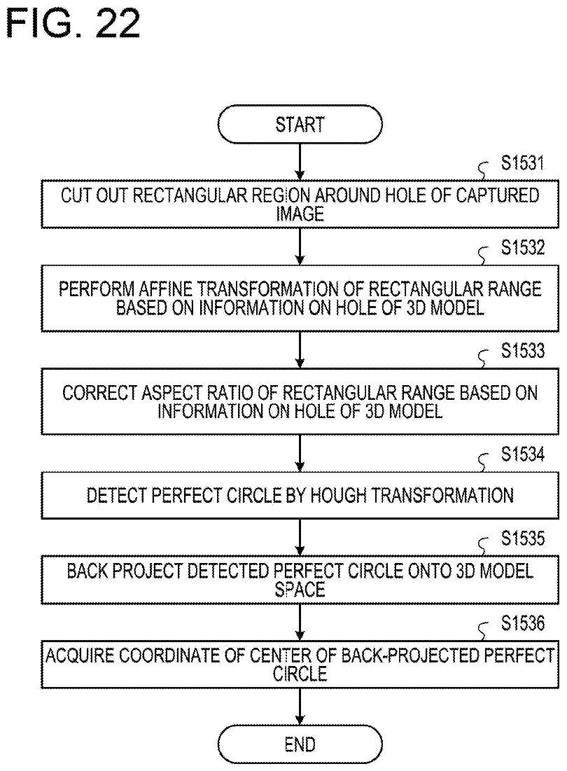

Details of step S153 will be described with reference to FIG. 22. FIG. 22 is a flowchart illustrating the flow of the process of detecting a perfect circle. As illustrated in FIG. 22, first, the information processing apparatus 10 cuts out a rectangular region around the hole on the captured image (step S1531).

Next, the information processing apparatus 10 performs affine transformation of the rectangular range based on the information on the hole in the 3D model (step S1532). In addition, the information processing apparatus 10 corrects the aspect ratio of the rectangular range based on the information on the hole in the 3D model (step S1533). Further, the information processing apparatus 10 detects a perfect circle from the rectangular range by Hough transformation (step S1534).

The information processing apparatus 10 backwardly projects the detected perfect circle onto the 3D model space (step S1535). Then, the information processing apparatus 10 acquires the coordinate of the center of the back-projected perfect circle (step S1536).

(Effects)

When it is detected that a hole formed in the structure is included in the target image that includes a captured image of the structure, the information processing apparatus 10 identifies the shape of the contour of the hole on the target captured image. The information processing apparatus 10 identifies a part of the 3D model such that, when the 3D model according to the 3D design data of the structure is projected onto the target captured image such that the projected image of the 3D model onto the target captured image corresponds to the captured image of the structure that is included in the target captured image, the part on the projected image corresponds to the shape. The information processing apparatus 10 outputs evaluation information related to a position at which the hole is formed in the structure based on the comparison result between the identified part and the part of the 3D model corresponding to the 3D design data of the hole. In this way, even when a hole appears to be elliptical depending on the image capturing angle or the like, the information processing apparatus 10 may project the image of the hole onto the same space as that of the 3D model and quantitatively calculate an error from the designed hole. Thus, according to the embodiment, the evaluation accuracy of the position of the hole formed in the structure may be improved.

The information processing apparatus 10 identifies the shape of the contour of the second hole formed in the structure on the target captured image, within the range determined based on the size of the first designed hole included in the 3D model on the projected image. The information processing apparatus 10 may detect the hole on the target captured image based on the hole in the 3D model. Thus, according to the embodiment, even when a number of holes exist in the 3D model and the structure, a hole to be compared may be identified easily.

The information processing apparatus 10 identifies the shape by combining a plurality of preset methods for each procedure for identifying the shape. The information processing apparatus 10 outputs the evaluation information based on the comparison result between the part identified based on the shape identified using a combination having the smallest predetermined cost function and the part of the 3D model corresponding to the 3D design data of the hole. The optimal method may differ depending on the position of a hole, the situation for capturing the target captured image, and the like. Meanwhile, in the embodiment, the optimal method may be selected from the combinations of the plurality of methods.

The information processing apparatus 10 uses a combination that minimizes the cost function of the first ellipse corresponding to the identified part and the second ellipse corresponding to the part of the 3D model corresponding to the 3D design data of the hole. The cost function increases with the increase in the area difference, the center-to-center distance, the formed angle and the difference between the major axis and the minor axis of the second ellipse. In this way, the information processing apparatus 10 may evaluate a combination of methods using only information related to the ellipse. Thus, according to the embodiment, it is possible to evaluate a combination of methods based on only information generated in calculation without acquiring additional information.

Further, the information processing apparatus 10 determines that among pixels of an image in the detection range, a pixel whose luminance value is included in a range from the first threshold value the second threshold value greater than the first threshold value is true. In addition, the information processing apparatus 10 determines that a pixel whose luminance value is not included in the range is false. The information processing apparatus 10 identifies the shape of the contour of the hole on the target captured image based on the image binarized into true and false. The shadow portion in the target captured image may have an extremely small luminance value. In addition, the highlight portion in the target captured image may have an extremely large luminance value. Further, the hole on the target captured image often becomes neither a shadow nor a highlight. For this reason, according to the embodiment, the contour of the hole may become clear by binarization.

In the above embodiment, the calculation unit 144 calculates the cost function based on the ellipse. However, as in the case of the error calculation, the calculation unit 144 may calculate the cost function regarding each ellipse as a perfect circle. Further, the output unit 145 may dismiss the combination related to the cost function when any value among the terms of the cost function is larger than a threshold value.

(System)

The processing procedures, control procedures, specific names, and information including various data and parameters described herein and in the drawings may be arbitrarily changed unless otherwise specified. Further, the specific examples, distributions, numerical values and the like described in the embodiment are merely examples and may be arbitrarily changed.

In addition, each component of each illustrated apparatus is functionally conceptual and is not necessarily required to be configured physically as illustrated. That is, specific forms of distribution or integration of the respective apparatuses are not limited to those illustrated. That is, all or a portion of the apparatuses may be configured to be functionally or physically distributed/integrated in arbitrary units according to, for example, various loads or usage conditions. Further, all or an arbitrary portion of the processing functions performed in each apparatus may be implemented by a CPU and a program that is analyzed and executed by the CPU, or may be implemented as hardware by a wired logic.

(Hardware)

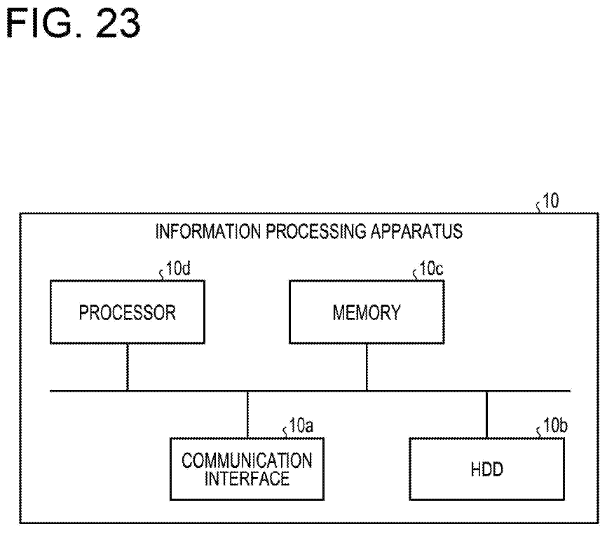

FIG. 23 is a view illustrating an example of a hardware configuration. As illustrated in FIG. 23, the information processing apparatus 10 includes a communication interface 10a, an HDD (Hard Disk Drive) 10b, a memory 10c, and a processor 10d. The respective units illustrated in FIG. 23 are coupled to each other by a bus or the like.

The communication interface 10a is a network interface card or the like, and communicates with other servers. The HDD 10b stores a program and a DB for operating the functions illustrated in FIG. 1.

The processor 10d operates a process for executing each function described in FIG. 1 and the like by reading a program for executing the same process as each processing unit illustrated in FIG. 1 from the HDD 10b or the like and deploying the program onto the memory 10c. That is, this process executes the same function as each processing unit included in the information processing apparatus 10. Specifically, the processor 10d reads a program having the same functions as the detector 141, the shape identifying unit 142, the part identifying unit 143, the calculation unit 144, and the output unit 145, from the HDD 10b or the like. Then, the processor 10d executes a process for executing the same processes as the detector 141, the shape identifying unit 142, the part identifying unit 143, the calculation unit 144, and the output unit 145. The processor 10d is a hardware circuit such as a CPU, MPU or ASIC.

In this way, the information processing apparatus 10 operates as an information processing apparatus that executes a classification method by reading and executing a program. Further, the information processing apparatus 10 may implement the same function as the above-described embodiment by reading the program from a recording medium by a medium reader and executing the read program. In addition, the program referred to in the other embodiments is not limited to being executed by the information processing apparatus 10. For example, the present disclosure may also be equally applied to a case where another computer or server executes the program, or a case where these computer and server cooperate to execute the program.

This program may be distributed via a network such as the Internet. In addition, the program may be recorded on a computer-readable recording medium such as a hard disk, a flexible disk (FD), a CD-ROM, an MO (Magneto-Optical disk), a DVD (Digital Versatile Disc) or the like, and may be executed when the program is read from the recording medium by a computer.

In one aspect, it is possible to improve the evaluation accuracy of a position of a hole formed in a structure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without, departing from the spirit and scope of the invention.

What is claimed is:

1. An evaluation method comprising:
identifying by a computer, when detecting that a hole formed in a structure is included in, a target captured image that includes a captured image of the structure, a shape of a contour of the hole on the target captured image;
identifying a part of a three-dimensional model such that, when the three-dimensional model according to three-dimensional design data of the structure is projected onto the target captured image such that a projected image of the three-dimensional model onto the target captured image corresponds to the captured image of the structure that is included in the target captured image, the part on the projected image corresponds to the shape; and
outputting evaluation information related to a position at which the hole is formed in the structure, based on a result of comparison between the identified part and a part of the three-dimensional model corresponding to the three-dimensional design data of the hole.

2. The evaluation method according to claim 1, further comprising:
identifying as the shape of the contour, within a range determined based on a size of a first designed hole that is included in the three-dimensional model on the projected image, a shape of a contour of a second hole formed in the structure on the target captured image.

3. The evaluation method according to claim 1, further comprising:
identifying shapes by using combinations of a plurality of methods set in advance for each procedure for identifying the shape; and
outputting the evaluation information based on a result of comparison between a part identified based on a shape identified by using a combination having a predetermined cost function that is smallest among the combinations and the part of the three-dimensional model corresponding to the three-dimensional design data of the hole.

4. The evaluation method according to claim 3, wherein
the cost function increases with increase in an area difference, a center-to-center distance, and a formed angle between a first ellipse and a second ellipse, and with increase in a distance between a major axis and a minor axis of the second ellipse, the first ellipse corresponding to the identified part, the second ellipse corresponding to the part of the three-dimensional model corresponding to the 3D design data of the hole.

5. The evaluation method according to claim 1, further comprising:
identifying the shape of the contour based on a binarized image in which, among pixels of an image in a region of the target captured image, a pixel having a luminance value in a range from a first threshold value to a second threshold value greater than the first threshold value is true and a pixel having a luminance value out of the range is false, the region including the detected hole.

6. A non-transitory computer-readable recording medium having stored therein a program that causes a computer to execute a process, the process comprising:
identifying, when detecting that a hole formed in a structure is included in a target captured image that includes a captured image of the structure, a shape of a contour of the hole on the target captured image;
identifying a part of a three-dimensional model such that, when the three-dimensional model according to three-dimensional design data of the structure is projected onto the target captured image such that a projected image of the three-dimensional model onto the target captured image corresponds to the captured image of the structure that is included in the target captured image, the part on the projected image corresponds to the shape; and
outputting evaluation information related to a position at which the hole is formed in the structure, based on a result of comparison between the identified part and a part of the three-dimensional model corresponding to the three-dimensional design data of the hole.

7. An information processing apparatus, comprising:
a memory; and
a processor coupled to the memory and the processor configured to:
identify, when detecting that a hole formed in a structure is included in a target captured image that includes a captured image of the structure, a shape of a contour of the hole on the target captured image;
identify a part of a three-dimensional model such that, when the three-dimensional model according to three-dimensional design data of the structure is projected onto the target captured image such that a projected image of the three-dimensional model onto the target captured image corresponds to the captured image of the structure that is included in the target captured image, the part on the projected image corresponds to the shape; and
output evaluation information related to a position at which the hole is formed in the structure, based on a result of comparison between the identified part and a part of the three-dimensional model corresponding to the three-dimensional design data of the hole.
